(19) United States
(12) Patent Application Publication
(10) Pub. No.: US 2023/0307319 A1
(43) Pub. Date: Sep. 28, 2023

(54) HEAT RADIATING MEMBER AND SEMICONDUCTOR MODULE

(71) Applicant: NIDEC CORPORATION, Kyoto (JP)

(72) Inventors: Koji MURAKAMI, Kyoto (JP); Yuki YANAGITA, Kyoto (JP)

(21) Appl. No.: 18/123,337

(22) Filed: Mar. 20, 2023

(30) Foreign Application Priority Data
Mar. 24, 2022 (JP) 2022-048856

(51) Int. Cl. H01L 23/473

(52) U.S. Cl. CPC H01L 23/473

(57) ABSTRACT

A heat radiating member includes a plate-shaped base portion and a plurality of fins protruding from the base portion toward one side. Assuming that a downstream side where the refrigerant flows is one side in the first direction, the fin has a flat plate-shaped sidewall. The sidewall is provided with a slit penetrating and a bent portion disposed on at least one of the one side in the first direction and the other side in the first direction of the slit and bent. The length of the bent portion is shorter than the first-direction length between the first-direction end of the slit facing the bent portion and the bending start position of the bent portion.

### CROSS-REFERENCE TO RELATED APPLICATIONS

The present invention claims priority under 35 U.S.C. § 119 to Japanese Patent Application No. 2022-048856 filed on Mar. 24, 2022, the entire content of which is incorporated herein by reference.

### FIELD OF THE INVENTION

The present disclosure relates to a heat radiating member.

### BACKGROUND

Conventionally, a cooling device including a water jacket used for water cooling and a heat radiating member is known. The heat radiating member includes cooling fins. The fins are accommodated in the water jacket. The inside of the water jacket serves as a flow path of cooling water, and a heating element is water-cooled through the fins.

In this case, in order to suppress clogging with contamination included in the cooling water, it is necessary to secure intervals between adjacent fins. However, when the intervals are widened, the installation density of the fins decreases to result in a deterioration in cooling performance.

### SUMMARY

An exemplary heat radiating member according to the present disclosure includes a plate-shaped base portion that extends in a first direction along a direction in which a refrigerant flows and in a second direction orthogonal to the first direction and has a thickness in a third direction orthogonal to the first direction and the second direction, and a plurality of fins protruding from the base portion toward one side in the third direction and arranged in the second direction. Assuming that a downstream side where the refrigerant flows is one side in the first direction, the fin has a flat plate-shaped sidewall that extends in the first direction and the third direction and has a thickness in the second direction. The sidewall is provided with a slit penetrating in the second direction and a bent portion disposed on at least one of the one side in the first direction and the other side in the first direction of the slit and bent in the second direction. The length of the bent portion is shorter than the first-direction length between the first-direction end of the slit facing the bent portion and the bending start position of the bent portion.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is a perspective view of a heat radiating member according to an exemplary embodiment of the present disclosure;

FIG. 2 is a side cross-sectional view of a heat radiating member;

FIG. 3 is a view schematically illustrating a part of an upper surface cross-section of a heat radiating fin portion;

FIG. 4 is a view illustrating a configuration according to a comparative example;

FIG. 5 is a view schematically illustrating a part of an upper surface cross-section of a heat radiating fin portion according to a first modification;

FIG. 6 is a view schematically illustrating a part of an upper surface cross-section of a heat radiating fin portion according to a second modification;

FIG. 7 is a side cross-sectional view of each of various heat radiating members with the inclination angle of a bent portion being changed;

FIG. 8 is a view illustrating an example of a simulation result; and

FIG. 9 is a side cross-sectional view of a heat radiating member according to a modification.

### DETAILED DESCRIPTION

Hereinafter, an exemplary embodiment of the present disclosure will be described with reference to the drawings.

In the drawings, with the first direction as an X direction, X1 indicates one side in the first direction, and X2 indicates the other side in the first direction. The first direction is a direction along a direction F in which a refrigerant W flows, and the downstream side is indicated by F1 and the upstream side is indicated by F2. The downstream side F1 is one side in the first direction, and the upstream side F2 is the other side in the first direction. With the second direction orthogonal to the first direction as a Y direction, Y1 indicates one side in the second direction, and Y2 indicates the other side in the second direction. With the third direction orthogonal to the first direction and the second direction as a Z direction, Z1 indicates one side in the third direction, and Z2 indicates the other side in the third direction. Note that the above-described “orthogonal” also includes intersection at an angle slightly shifted from 90°. Each of the above-described directions does not limit a direction when a heat radiating member 5 is incorporated in various devices.

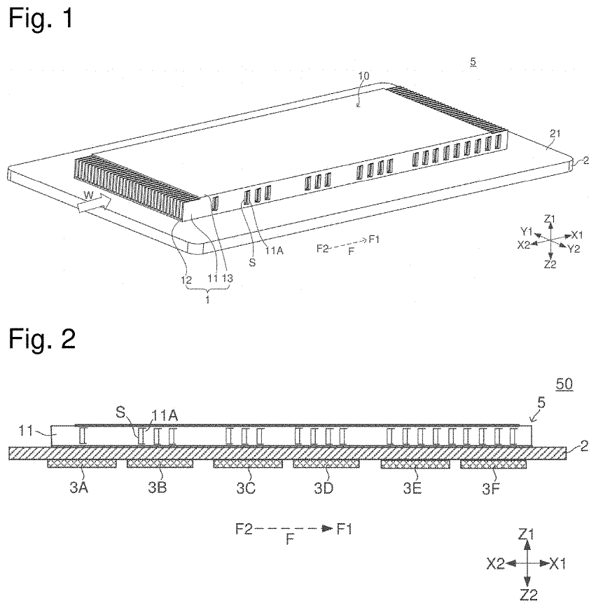

FIG. 1 is a perspective view of the heat radiating member 5 according to an exemplary embodiment of the present disclosure. FIG. 2 is a side cross-sectional view of the heat radiating member 5. FIG. 2 is a view illustrating a state in which the heat radiating member 5 is cut along a cut surface orthogonal to the second direction at a halfway position in the second direction as viewed from one side in the second direction.

A cooling device includes the heat radiating member 5 and a liquid cooling jacket (not illustrated) in which the heat radiating member 5 is installed. The cooling device is a device for cooling a plurality of semiconductor devices 3A, 3B, 3C, 3D, 3E, and 3F (to be referred to as the semiconductor device 3A and the like) (see FIG. 2). The semiconductor device is an example of a heating element. The semiconductor device 3A and the like are power transistors of an inverter included in a traction motor for driving wheels of a vehicle, for example. The power transistor is, for example, an insulated gate bipolar transistor (IGBT). In this case, the cooling device is mounted on the traction motor. Note that the number of semiconductor devices may be plural other than six or may be one.

The heat radiating member 5 includes a base portion 2 and a heat radiating fin portion 10. The base portion 2 has a plate shape that extends in the first direction and the second direction and has a thickness in the third direction. The base portion 2 is made of a metal having high thermal conductivity, for example, a copper alloy.

The heat radiating fin portion 10 is fixed to one side of the base portion 2 in the third direction. The heat radiating fin portion 10 is configured as a so-called stacked fin formed by arranging a plurality of fins 1 formed of one metal plate extending in the first direction in the second direction. The fin 1 is made of, for example, a copper plate.

The fin 1 includes a sidewall 11, a bottom plate portion 12, and a top plate portion 13. The sidewall 11 has a flat plate shape that extends in the first direction and the third direction and has a thickness in the second direction.

The bottom plate portion 12 is bent toward one side in the second direction at the third-direction other end portion of the sidewall 11. The top plate portion 13 is bent toward one side in the second direction at third-direction one end portion of the sidewall 11. Accordingly, a cross-section of the fin 1 has a rectangular U-shape. The heat radiating fin portion 10 having the fins 1 stacked in the second direction is fixed to the base portion 2 by fixing the bottom plate portion 12 to third-direction one side surface 21 of the base portion 2 by, for example, brazing. That is, the heat radiating member 5 has a plurality of fins 1 protruding from the base portion 2 toward one side in the third direction and arranged in the second direction.

The heat radiating fin portion 10 is accommodated in a liquid cooling jacket (not illustrated). As illustrated in FIG. 1, a refrigerant W flowing into the liquid cooling jacket flows into the heat radiating fin portion 10 from the other side (upstream side) in the first direction. The refrigerant W is, for example, water or an ethylene glycol aqueous solution. The refrigerant W flows to one side in the first direction inside the flow path formed between the fins 1 adjacent in the second direction, is discharged from the heat radiating fin portion 10, and is then discharged to the outside from the liquid cooling jacket. The semiconductor device 3A and the like are disposed on the other side of the base portion 2 in the third direction (see FIG. 2). Heat generated from the semiconductor device 3A and the like moves to the refrigerant W through the base portion 2 and the fins 1, whereby the semiconductor device 3A and the like are cooled. Note that a semiconductor module 50 includes the heat radiating member 5 and the semiconductor device 3A and the like disposed on the other side of the base portion 2 in the third direction (see FIG. 2).

As illustrated in FIGS. 1 and 2, the fin 1 has a bent portion 11A. A configuration related to the bent portion 11A will be described below.

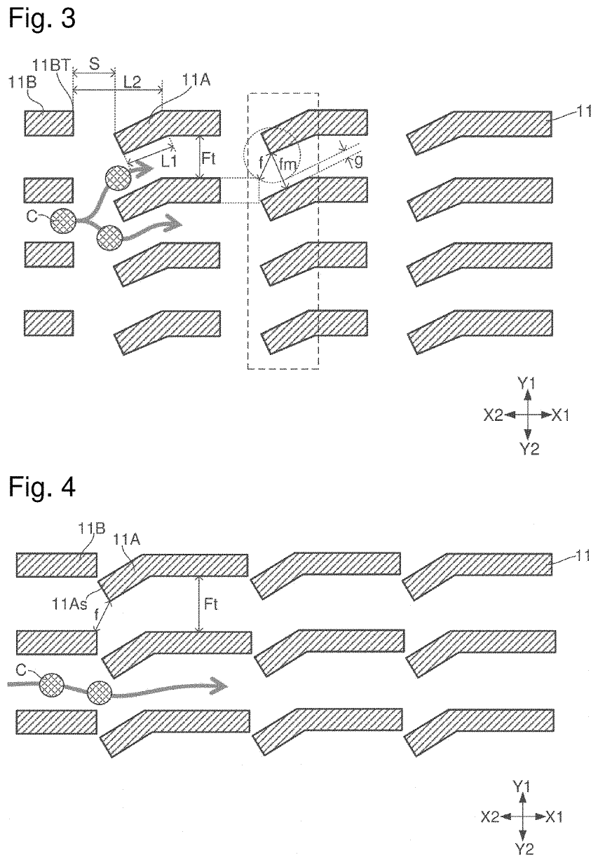

FIG. 3 is a view schematically illustrating a part of an upper surface cross-section of the heat radiating fin portion 10. FIG. 3 is a view illustrating a state in which the heat radiating fin portion 10 is cut at a halfway position in the third direction along a cross-section orthogonal to the third direction as viewed from the other side in the third direction. The same applies to FIGS. 4, 5, and 6.

As illustrated in FIG. 3 (FIGS. 1 and 2), the sidewall 11 of the fin 1 is provided with a bent portion 11A bent toward the other side in the second direction. A slit S penetrating in the second direction is provided between a part 11B of the sidewall 11 located on the other side of the bent portion 11A in the first direction and the bent portion 11A. That is, the sidewall 11 is provided with the slit S penetrating in the second direction and the bent portion 11A disposed on one side of the slit S in the first direction and bent in the second direction. Providing the bent portion 11A can generate a turbulent flow, break a boundary layer growing along the sidewall 11, and improve the cooling performance.

A length L1 of the bent portion 11A is shorter than a first-direction length L2 between the part 11B of the sidewall 11 and the bending start position of the bent portion 11A. That is, the length L1 of the bent portion 11A is shorter than the first-direction length L2 between a first-direction end 11BT facing the bent portion 11A of the slit S and the bending start position of the bent portion 11A.

In this case, for comparison with the present embodiment, FIG. 4 illustrates a configuration in a case where the slit S is not provided between the part 11B of the sidewall 11 and the bent portion 11A in the sidewall 11. In this case, a gap f between a tip portion 11As of the bent portion 11A and the part 11B of the sidewall 11 disposed on the other side of the tip portion 11As in the first direction which is adjacent to the other side of the tip portion 11As in the second direction tends to be narrowed by bending of the bent portion 11A. In order to suppress clogging with contamination C included in the refrigerant W flowing between the fins 1 adjacent in the second direction, the minimum gap f needs to satisfy the following condition.

f=Dc+α
where Dc is the diameter of the contamination C, and α is a margin.

In contrast to this, in the configuration according to the present embodiment illustrated in FIG. 3, the minimum gap becomes fm by providing the slit S and is represented by fm=f+g. That is, in the case of Ft that is the same as that in FIG. 4, fm=Dc+α+g, and the minimum gap is enlarged by g. Even if the minimum gap fm is reduced by g, clogging with the contamination C can be suppressed. That is, according to the present embodiment, it is possible to reduce the interval Ft while taking measures against contamination. Therefore, the installation density of the fins 1 can be increased, and the cooling performance can be improved.

Further, as surrounded by the broken line in FIG. 3, the plurality of bent portions 11A arranged side by side in the second direction at the same first-direction position are bent to the same side (the other side in the second direction) in the second direction. This makes it possible to suppress contamination clogging due to the narrowing of the interval between the adjacent bent portions 11A.

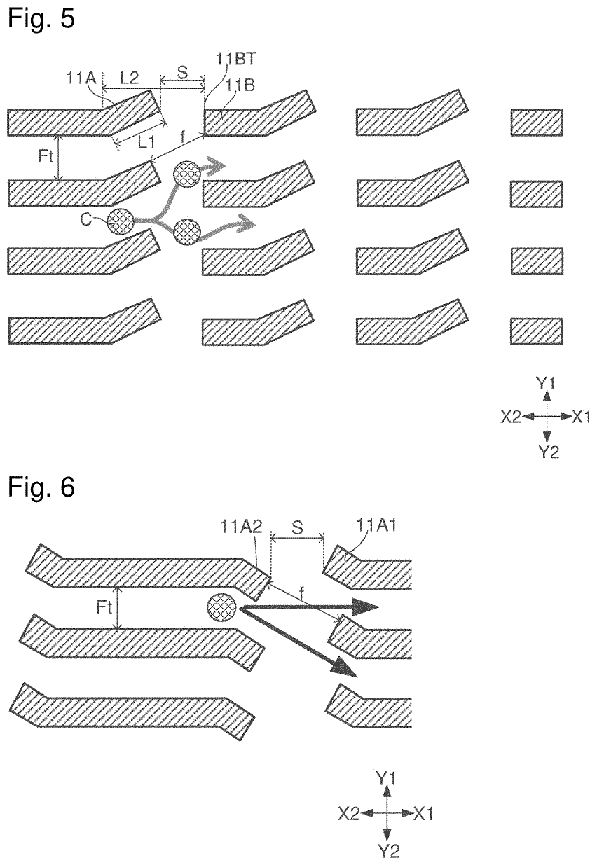

FIG. 5 is a view schematically illustrating a part of an upper surface cross-section of the heat radiating fin portion 10 according to a first modification. In the configuration illustrated in FIG. 5, the sidewall 11 is provided with the bent portion 11A bent toward one side in the second direction. A slit S penetrating in the second direction is provided between a part 11B of the sidewall 11 located on one side of the bent portion 11A in the first direction and the bent portion 11A. That is, the sidewall 11 is provided with the bent portion 11A disposed on the other side of the slit S in the first direction and bent in the second direction. The length L1 of the bent portion 11A is shorter than the first-direction length L2 between the first-direction end 11BT facing the bent portion 11A of the slit S and the bending start position of the bent portion 11A.

Even with such a configuration, even if the interval Ft between the fins 1 is narrowed, the gap f is widened, and the cooling performance can be improved while suppressing contamination clogging.

FIG. 6 is a view schematically illustrating a part of an upper surface cross-section of the heat radiating fin portion 10 according to a second modification. In the configuration illustrated in FIG. 6, the sidewall 11 is provided with a bent portion 11A1 bent toward one side in the second direction and a bent portion 11A2 bent toward the other side in the second direction. The slit S penetrating in the second direction is provided between the bent portion 11A1 and the bent portion 11A2. That is, the sidewall 11 is provided with the bent portions 11A1 and 11A2 disposed on one side in the first direction and the other side in the first direction of the slit S and bent in the second direction.

Even with such a configuration, even if the interval Ft between the fins 1 is narrowed, the gap f between the bent portions 11A1 and 11A2 is widened, and the cooling performance can be improved while suppressing contamination clogging.

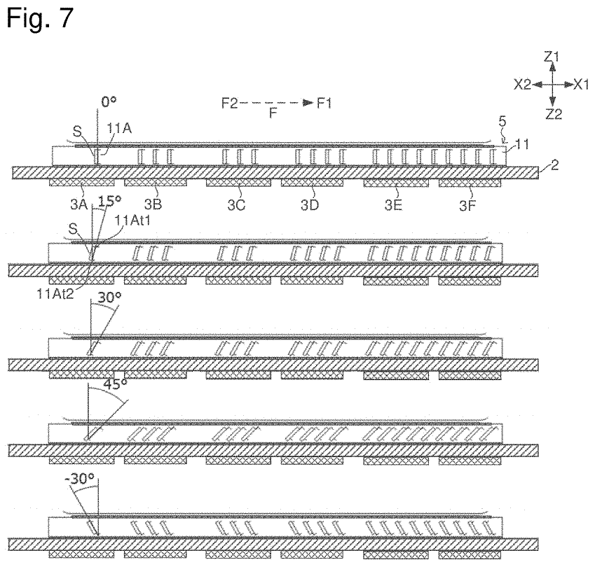

The bent portion 11A may be inclined with respect to the third direction as viewed in the second direction. FIG. 7 is a side cross-sectional view of each of various heat radiating members 5 having such a configuration. FIG. 7 illustrates a configuration example in which the inclination angle of the bent portion 11A is changed. Note that, on the uppermost part of FIG. 7, a configuration example of the bent portion 11A that is not inclined is also illustrated.

As illustrated in FIG. 7, regarding the inclined bent portion 11A, specifically, the first-direction end of the bent portion 11A viewed in the second direction, third-direction one end 11At1 is located on one side in the first direction with respect to the third-direction other end 11At2. That is, the third-direction one end 11At1 away from the base portion 2 is located downstream of the third-direction other end 11At2 on the base portion 2 side. As a result, a reverse pressure gradient is generated on the downstream side of the bent portion 11A, the flow of the back flow is stagnated, and the flow velocity of the refrigerant W is increased on the base portion 2 side where the flow of the back flow is not stagnated, so that the cooling performance can be further improved.

In this case, the slit S is also inclined, and the above-described first-direction length L2 is a length along the side of the slit S. That is, the first-direction length L2 is a length in a direction including the first-direction component.

As illustrated in FIG. 7, a first-direction end of the bent portion 11A viewed in the second direction is inclined at an inclination angle θ with respect to the third direction. FIG. 7 exemplifies the cases of θ=15°, 30°, 45°, and −30°.

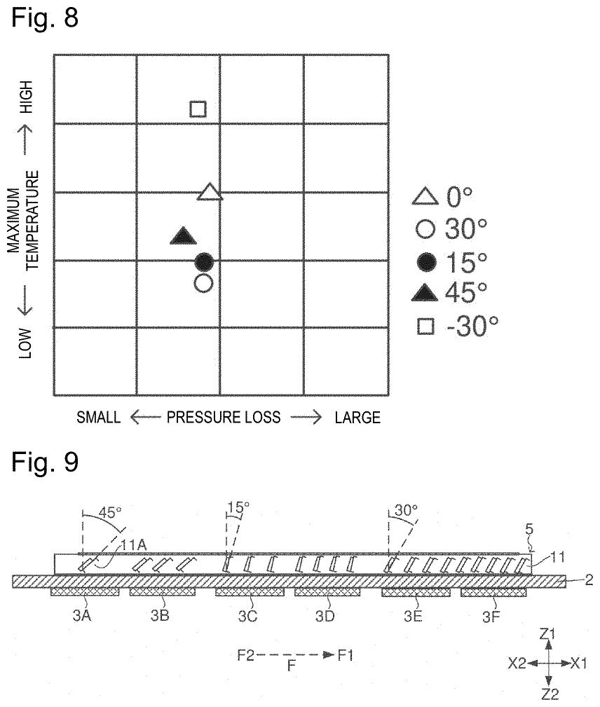

FIG. 8 illustrates the results of simulations performed on a model having a configuration in which the bent portion 11A is inclined at θ=15°, 30°, 45°, and −30°. Referring to FIG. 8, the simulation results of the pressure loss and the maximum temperature of the semiconductor device 3A and the like are plotted.

As illustrated in FIG. 8, when the first-direction end of the bent portion 11A viewed in the second direction is inclined at 30° with respect to the third direction, the maximum temperature is the lowest, which is suitable in a case where priority is given to cooling performance.

As illustrated in FIG. 8, when the first-direction end of the bent portion 11A viewed in the second direction is inclined at 45° with respect to the third direction, the pressure loss is the lowest, which is suitable in a case where the reduction of the pressure loss is prioritized.

As illustrated in FIG. 8, when the first-direction end of the bent portion 11A viewed in the second direction is inclined at 15° with respect to the third direction, it is suitable when both the pressure loss performance and the cooling performance are required.

The reason why the cooling performance decreases at θ=−30° is that a reverse pressure gradient is generated on the downstream side of the bent portion 11A, and the flow of the back flow stagnates, but the flow velocity of the refrigerant W increases on the side opposite to the base portion 2 where the flow does not stagnate, and the flow velocity decreases on the base portion 2 side.

Furthermore, in view of the above effects, the heat radiating member 5 having a configuration as illustrated in the side cross-sectional view of FIG. 9 may be adopted. Referring to FIG. 9, the bent portion 11A inclined at θ=45° is provided corresponding to the upstream semiconductor devices 3A and 3B, the bent portion 11A inclined at θ=15° is provided corresponding to the central semiconductor devices 3C and 3D, and the bent portion 11A inclined at θ=30° is provided corresponding to the downstream semiconductor devices 3E and 3F.

Accordingly, it is possible to prioritize the pressure loss reduction performance on the upstream side where the temperature of the refrigerant W is low and the cooling performance is relatively unnecessary, to prioritize the cooling performance on the downstream side where the temperature of the refrigerant W is high and the cooling performance is relatively necessary, and to secure both the pressure loss reduction performance and the cooling performance to some extents at the center. Therefore, it is possible to suppress the temperature difference between the semiconductor device 3A and the like while suppressing the entire pressure loss.

In other words, the bent portion 11A includes a plurality of bent portions arranged in the first direction. The inclination angle θ of the first-direction end of the bent portion 11A with respect to the third direction as viewed in the second direction changes in the first direction. As a result, it is possible to suppress the temperature difference between the heating elements while suppressing an increase in pressure loss as a whole as described above.

The embodiment of the present disclosure is described above. Note that the scope of the present disclosure is not limited to the above embodiment. The present disclosure can be implemented by making various changes to the above-described embodiment without departing from the gist of the invention. The matters described in the above embodiment can be optionally combined together, as appropriate, as long as there is no inconsistency.

The present disclosure can be used for cooling various heating elements.

Features of the above-described preferred embodiments and the modifications thereof may be combined appropriately as long as no conflict arises.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A heat radiating member comprising:
a plate-shaped base portion that extends in a first direction along a direction in which a refrigerant flows and in a second direction orthogonal to the first direction and has a thickness in a third direction orthogonal to the first direction and the second direction; and
a plurality of fins protruding from the base portion toward one side in the third direction and arranged in the second direction,
wherein assuming that a downstream side where the refrigerant flows is one side in the first direction,
the fin includes a flat plate-shaped sidewall that extends in the first direction and the third direction and has a thickness in the second direction,
the sidewall is provided with
a slit penetrating in the second direction and
a bent portion disposed on at least one of the one side in the first direction and the other side in the first direction of the slit and bent in the second direction, and
a length of the bent portion is shorter than a first-direction length between a first-direction end of the slit facing the bent portion and a bending start position of the bent portion.

2. The heat radiating member according to claim 1, wherein a plurality of the bent portions arranged side by side in the second direction at a same first-direction position are bent to a same side in the second direction.

3. The heat radiating member according to claim 1, wherein third-direction one end is located closer to the one side in the first direction than the third-direction other end at a first-direction end of the bent portion as viewed in the second direction.

4. The heat radiating member according to claim 3, wherein a first-direction end of the bent portion as viewed in the second direction is inclined at 15° with respect to the third direction.

5. The heat radiating member according to claim 3, wherein a first-direction end of the bent portion as viewed in the second direction is inclined at 30° with respect to the third direction.

6. The heat radiating member according to claim 3, wherein a first-direction end of the bent portion as viewed in the second direction is inclined at 45° with respect to the third direction.

7. The heat radiating member according to claim 3, wherein
a plurality of the bent portions are disposed in a first direction, and
an inclination angle of a first-direction end of the bent portion with respect to a third direction as viewed in the second direction changes in the first direction.

8. A semiconductor module comprising:
the heat radiating member according to claim 1; and
a semiconductor device disposed on the other side of the base portion in the third direction.
